(19) United States
(12) Patent Application Publication
(10) Pub. No.: US 2010/0075497 A1
(43) Pub. Date: Mar. 25, 2010

(54) Non-Plating Line Plating Method Using Current Transmitted From Ball Side

(76) Inventors: Chien-Wei Chang, Taoyuan (TW); Ting-Hao Lin, Taipei (TW); Yu-Te Lu, Taoyuan (TW)

Correspondence Address: LIN & ASSOCIATES INTELLECTUAL PROPERTY, INC., P.O. BOX 2339, SARATOGA, CA, 95070-0339, US

(21) Appl. No.: 12/236,493

(22) Filed: Sep. 23, 2008

(51) Int. Cl. H01L 21/44; H01L 21/288

(52) U.S. Cl. 438/669; 205/123; 257/E21.582

(57) ABSTRACT

A non-plating line (NPL) plating method is provided. The NPL plating method is featured in that at first it forms a circuit layer on a bump side only, and therefore a plating current can be transmitted via a plating metal layer on a ball side to the circuit layer (enclosed by an insulation layer, e.g., a solder resist or a photoresist) on the bump side, and thus forming a protection layer, e.g., plating gold, on the plating metal layer on the circuit layer and the ball side. In such a way, the plating gold is formed after the insulation layer, so that there won't be any plating gold existed beneath the insulation layer of the bump side (connected with dies). Hence, the insulation layer can be prevented from dropping off from the protection layer, i.e., the plating gold, and thus the reliability of the products can be improved.

### BACKGROUND OF THE INVENTION

1. Field of the Invention

The present invention generally relates to a plating method, and more particularly, to a non-plating line (NPL) plating method using current transmitted from a ball side.

2. The Prior Arts

Currently, electronic products are more often packaged with environmental friendly materials. In order to satisfy the demand for lead free or even halogen free environmental friendly materials, the reliability of the IC carrier board must be more critically concerned. In this circumstance, if a lead free material is used as a soldering tin, the melting point of the soldering tin will be much higher than the conventional solder tin. And therefore, the reliability and heat resistance of the carrier board are correspondingly required to be much better. Unfortunately, this raises many other problems caused by the high temperature processing environment for the IC manufacturers to overcome.

For the purpose of improving electric properties and reducing noise, currently the carrier boards are mostly modified with an NPL design, while wire bonding areas are still desired to be electroplated with nickel/gold (Ni/Au) for achieving a better bondability. Even though an electroless nickel and immersion gold (ENAG) process may be used for fabricating the wire bonding areas, the wire bonding areas fabricated by such an ENAG process are evaluated with an unsatisfactory reliability. As such, an NPL wire bonding block configured by electroplating Ni/Au is often fabricated by a gold pattern plating (GPP) (e.g., full body gold) process.

However, before performing such a GPP process, an electroplating Ni/Au layer has been formed earlier than the solder mask (SM), and therefore a relatively large area of the electroplating Ni/Au layer is covered by the SM. Since it is well known that the SM is featured of a poor bondability with gold, the GPP method becomes incapable of satisfying the current requirements for a higher reliability and a better heat resistance.

Further, the NPL process is very complicated. The NPL process even requires for a specific machine for plating a thin copper layer. Parameters of etching the thin copper layer after plating the same are very difficult to control, during which micro short often occurs or a reliability test causes micro short so as to bring serious consequence.

The present invention provides a method for forming an insulation layer (e.g., a photoresist layer) first and then forming an electroplating Ni/Au layer. The Ni/Au layer is plated without plating lines, and therefore adapted for avoiding all of the foregoing disadvantages.

### SUMMARY OF THE INVENTION

A primary objective of the present invention is to provide an NPL plating method using current transmitted from a ball side. The NPL plating method is featured in that at first it forms a circuit layer on a bump side only, and therefore a plating current can be transmitted via a plating metal layer on a ball side to the circuit layer (enclosed by an insulation layer, e.g., a solder resist or a photoresist) on the bump side, and thus forming a protection layer, e.g., plating gold, on the plating metal layer on the circuit layer and the ball side. In such a way, the plating gold is formed after the insulation layer, so that there won't be any plating gold existed beneath the insulation layer of the bump side (connected with dies). Hence, the insulation layer can be prevented from dropping off from the protection layer, i.e., the plating gold, and thus the reliability of the products can be improved.

For achieving the foregoing objective of the present invention, the present invention provides an NPL plating method using current transmitted from a ball side. First, a carrier board is provided. The carrier board has a ball side and a bump side, and at least one pin through hole (PTH). A plating metal layer is formed on the surfaces of the ball side and the bump side, as well as a wall surface of the PTH. The ball side and the bump side are electrically connected via the plating metal layer. Then, only the plating metal layer on the bump side is patterned to form a first circuit layer. Then, an insulation layer is formed at a periphery of the first circuit layer while exposing a part of the first circuit layer. Finally, a plating current is transmitted from the plating metal layer on the ball side to the first circuit layer on the bump side, so as to form a first protection layer on the exposed part of the first circuit layer.

### BRIEF DESCRIPTION OF THE DRAWINGS

The present invention will be apparent to those skilled in the art by reading the following detailed description of a preferred embodiment thereof, with reference to the attached drawings, in which:

FIGS. 1A through 1F are schematic diagrams illustrating an NPL plating method using current transmitted from a ball side according to an embodiment of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

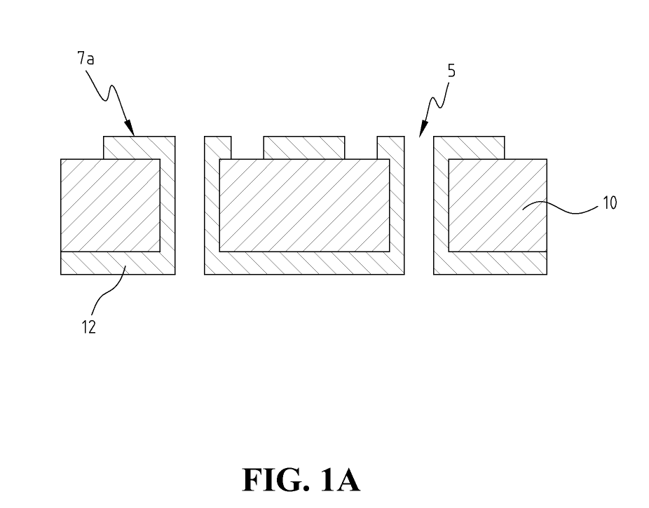

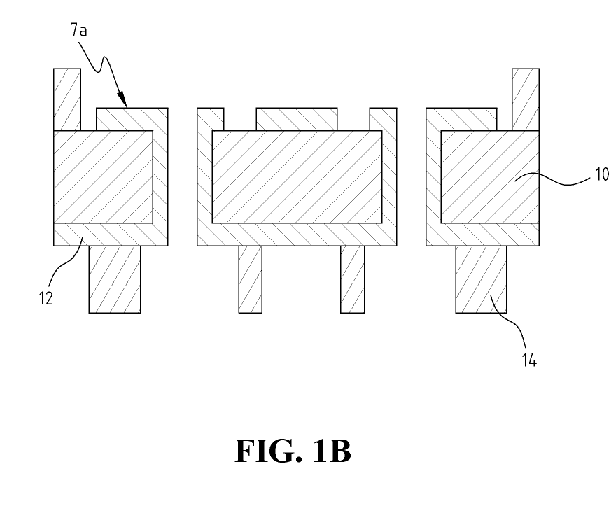

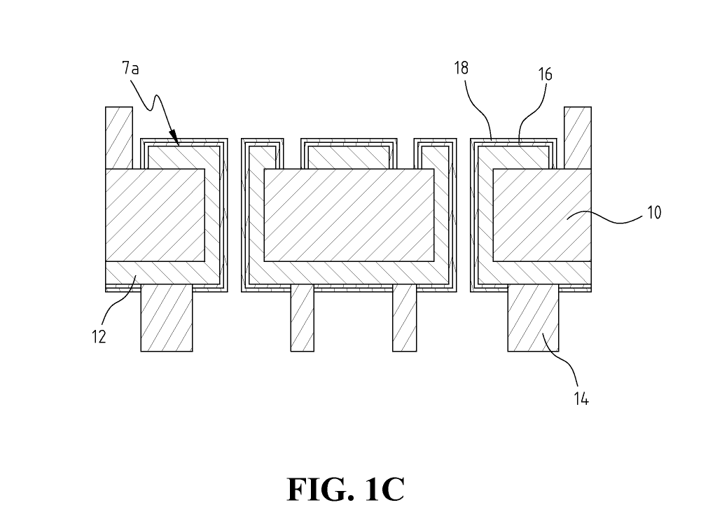

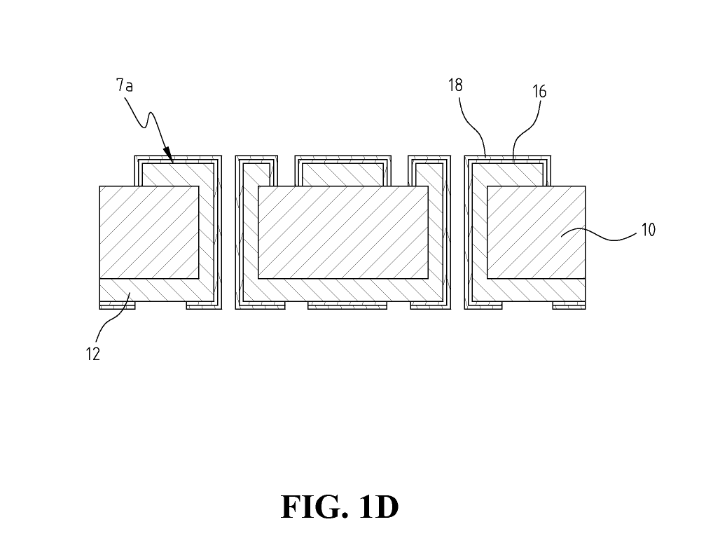

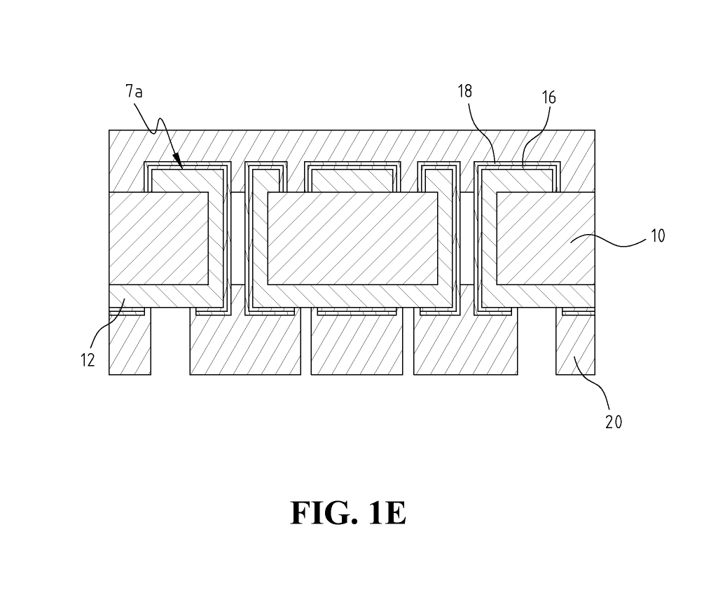

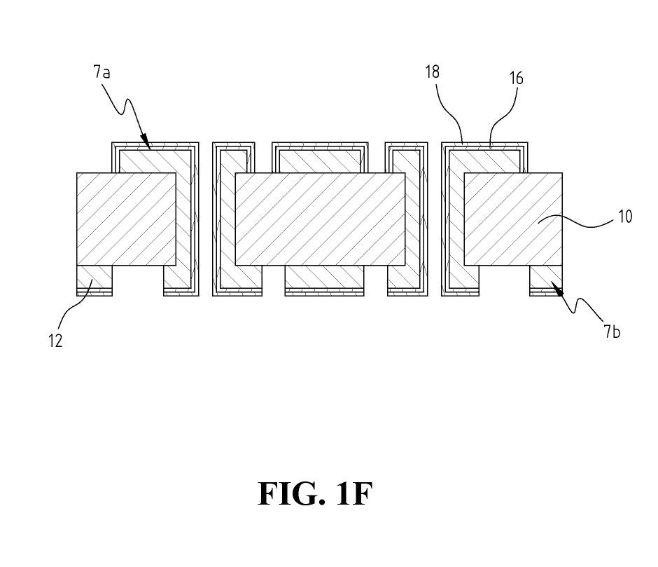

FIGS. 1A through 1F are schematic diagrams illustrating an NPL plating method using current transmitted from a ball side according to an embodiment of the present invention. As shown in FIG. 1A, before executing the NPL plating method of the present invention, a substrate 10 covered with a copper reduction has been previously prepared. The substrate 10 has a bump side and a ball side. The substrate 10 covered with the copper reduction is drilled by laser or mechanical drilling to configure at least one pin through hole (PTH) 5. Then, a plating metal layer 12 is formed on surfaces of the bump side, the ball side and a wall surface of the PTH 5 of the substrate 10.

In accordance with the NPL plating method, a first circuit layer 7a as shown in FIG. 1A is formed on the bump side of the substrate 10. Because the first circuit layer 7a is electrically connected with the plating metal layer 12 on the ball side of the substrate 10, a plating current is transmitted from the plating metal layer 12 on the ball side as shown in FIG. 1C to the first circuit layer 7a which has been enclosed by an insulation layer 14 at a periphery of the first circuit layer 7a, so as to form a first protection layer 16 (plating gold) on the first circuit layer 7a and the plating metal layer 12 on the ball side as shown in FIG. 1C. Then, the first circuit layer 7a on the bump side is attached with dies. Further, in order to provide further protection to the plating metal layer 12, a second protection layer 18 can be formed by plating on the first protection layer 16.

In such a way, the plating gold is formed after the insulation layer 14, so that there won't be any plating gold existed beneath the insulation layer 14 of the bump side (connected with dies). Hence, the insulation layer 14 can be prevented from dropping off from the plating metal layer, and thus the reliability of the products can be improved.

As shown in FIG. 1D, in order to fabricate a second circuit layer 7b as shown in FIG. 1F, the insulation layer 14 is removed. And therefore, as shown in FIG. 1E, an insulation layer 20 is provided entirely covering the second protection layer 18 and the substrate 10 on the bump side and selectively covering the second protection layer 18 and the substrate 10 on the ball side. In other words, the insulation layer 20 provided on the ball side is adapted for selectively exposing a part that is uncovered by the second protection layer 18, i.e., exposing a part of the plating metal layer 12 which is desired to be removed. In such a way, the exposed part of the plating metal layer 12 is removed, and the substrate 10 thereunder is exposed. Meanwhile, the insulation layer 20 is also removed, and thus the second circuit layer 7b is formed as shown in FIG. 1F.

The foregoing protection layer 16, second protection layer 18 can be plating gold, plating nickel, or a combination thereof, while the insulation layer 14 and the insulation layer 20 can be solder resist or photoresist.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1 A non-plating line (NPL) plating method using current transmitted from a ball side, comprising the steps of:
providing a carrier board having a bump side, a ball side, and a pin through hole, wherein a plating metal layer is formed on surfaces of the bump side and the ball side, and a wall of the pin through hole, the ball side and the bump side being electrically connected by the plating metal layer formed on the wall of the pin through hole;
patterning the plating metal layer on the bump side only, to form a first circuit layer, wherein the first circuit layer is electrically connected to the metal plating layer on the ball side by the plating metal layer on the wall of the pin through hole;
forming an insulation layer at a periphery of the first circuit layer and on the plating metal layer on the ball side, while remaining a part of the first circuit layer exposed, and remaining a part of the plating metal layer on the ball side exposed; and
transmitting a plating current from the plating metal layer on the ball side to the first circuit layer on the bump side, so as to form a first protection layer on the exposed part of the first circuit layer and the exposed part of the plating metal layer on the ball side.

2. The method according to claim 1, wherein the insulation layer is a solder resist or a photoresist.

3. The method according to claim 1, further comprising the step of forming a second protection layer on the first protection layer.

4. The method according to claim 3, wherein the first protection layer and the second protection layer are plating gold, plating nickel, or a combination thereof.
